(19) United States
(12) Patent Application Publication
(10) Pub. No.: US 2018/0363926 A1
(43) Pub. Date: Dec. 20, 2018

(54) Heat-Pump System With Refrigerant Charge Diagnostics

(71) Applicant: Emerson Climate Technologies, Inc., Sidney, OH (US)

(72) Inventors: Fadi M. ALSALEEM, Omaha, NE (US); Gregg M. HEMMELGARN, Yorkshire, OH (US)

(73) Assignee: Emerson Climate Technologies, Inc., Sidney, OH (US)

(21) Appl. No.: 16/113,271

(22) Filed: Aug. 27, 2018

Related U.S. Application Data
(62) Division of application No. 14/607,782, filed on Jan. 28, 2015, now Pat. No. 10,060,636.
Application No. 14/607,782 is a continuation of application No. 14/244,967, filed on Apr. 4, 2014, now Pat. No. 9,765,979.
(60) Provisional application No. 61/808,688, filed on Apr. 5, 2013.

(51) Int. Cl. F24D 19/10; F25B 49/00; F25B 13/00

(52) U.S. Cl. CPC F24D 19/1087; H05K 999/99; F25B 49/00; F25B 49/005; F25B 2700/21161; F25B 2700/2106; F25B 2500/24; F25B 2500/23; F25B 2500/22; F25B 13/00; F25B 2700/21163; F25B 2700/21172; F25B 2700/21173; F24D 2220/042

(57) ABSTRACT

A heat-pump circuit may include an indoor heat exchanger, an outdoor heat exchanger, a compressor adapted to circulate a working fluid between the indoor and outdoor heat exchangers, and an expansion device disposed between the indoor and outdoor heat exchangers. A monitor for the heat-pump system may include a return-air temperature sensor, a supply-air temperature sensor, and a processor. The return-air temperature sensor may be adapted to measure a first air temperature of air upstream of the indoor heat exchanger. The supply-air temperature sensor may be adapted to measure a second air temperature of air downstream of the indoor heat exchanger. The processor may be in communication with the return-air temperature sensor and the supply-air temperature sensor. The processor may be programmed to determine a working-fluid-charge condition of the heat-pump system based on the first and second air temperatures.

### CROSS-REFERENCE TO RELATED APPLICATIONS

This application is a divisional of U.S. patent application Ser. No. 14/607,782 filed on Jan. 28, 2015, which is a continuation of U.S. patent application Ser. No. 14/244,967 (now U.S. Pat. No. 9,765,979) filed on Apr. 4, 2014, which claims the benefit of U.S. Provisional Application No. 61/808,688 filed on Apr. 5, 2013. The entire disclosures of the above applications are incorporated herein by reference.

### FIELD

The present disclosure relates to a heat-pump system having refrigerant charge diagnostics.

### BACKGROUND

This section provides background information related to the present disclosure and is not necessarily prior art.

A climate-control system such as, for example, a heat-pump system, a refrigeration system, or an air conditioning system, may include a fluid circuit having an outdoor heat exchanger, an indoor heat exchanger, an expansion device disposed between the indoor and outdoor heat exchangers, and a compressor circulating a working fluid (e.g., refrigerant or carbon dioxide) between the indoor and outdoor heat exchangers. Maintaining proper amounts of working fluid in the system (i.e., refrigerant charge levels) is desirable for effective and efficient operation of the climate-control system.

### SUMMARY

This section provides a general summary of the disclosure, and is not a comprehensive disclosure of its full scope or all of its features.

In one form, the present disclosure provides a method that may include determining a working-fluid-charge condition of a heat-pump system based on at least one of a supply-air temperature and a return-air temperature. In some embodiments, the working-fluid charge condition may be determined by a cloud-based processing device.

In another form, a monitor may be provided for a heat-pump circuit. The heat-pump circuit may include an indoor heat exchanger, an outdoor heat exchanger, a compressor circulating a working fluid between the indoor and outdoor heat exchangers, and an expansion device between the indoor and outdoor heat exchangers. The monitor may include a return-air temperature sensor, a supply-air temperature sensor, and a processor. The return-air temperature sensor may be adapted to measure a first air temperature of air upstream of the indoor heat exchanger. The supply-air temperature sensor may be adapted to measure a second air temperature of air downstream of the indoor heat exchanger. The processor may be in communication with the return-air temperature sensor and the supply-air temperature sensor. The processor may be programmed to determine a working-fluid-charge condition of the heat-pump system based on the first and second air temperatures.

In some embodiments, the processor is programmed to determine the working-fluid-charge condition based on a difference between the second air temperature and the first air temperature and a comparison of the difference with a predetermined value.

In some embodiments, the monitor includes a working-fluid temperature sensor disposed between the expansion device and the indoor heat exchanger and adapted to measure a working-fluid temperature of working fluid flowing between the indoor heat exchanger and the expansion device when the heat-pump system is operating in a heating mode. The processor may be in communication with the working-fluid temperature sensor and may be programmed to determine the working-fluid-charge condition of the heat-pump system based on the working-fluid temperature.

In some embodiments, the processor is programmed to determine the working-fluid-charge condition based a first difference between the second air temperature and the working-fluid temperature.

In some embodiments, the processor is programmed to determine the working-fluid-charge condition based on a second difference between the second air temperature and the first air temperature.

In some embodiments, the processor is programmed to determine the working-fluid charge condition based only on a first comparison of the first difference with a first predetermined value and a second comparison of the second difference with a second predetermined value.

In some embodiments, the processor is programmed to determine the working-fluid-charge condition based a third difference between the working-fluid temperature and the second air temperature.

In some embodiments, the processor is programmed to determine the working-fluid charge condition based on a first comparison of the first difference with a first predetermined value, a second comparison of the second difference with a second predetermined value, and a third comparison of the third difference with a third predetermined value.

In some embodiments, the processor is in communication with a notification device configured to generate a first alert indicating that a fault condition of the heat-pump system is related to the working-fluid-charge condition and a second alert indicating that the fault condition of the heat-pump system is unrelated to an amount of working fluid in the heat-pump system.

In some embodiments, the processor is a cloud-based processor. The notification device may include a mobile, wireless computing device, for example.

In some embodiments, the processor is in communication with a notification device configured to generate an alert indicating the working-fluid-charge condition.

In some embodiments, the processor is a cloud-based processor disposed remotely from the compressor, the return-air temperature sensor and the supply-air temperature sensor.

In another form, the present disclosure provides a method of monitoring a heat-pump system. The heat-pump system may include indoor and outdoor heat exchangers, a compressor adapted to circulate a working fluid between the indoor and outdoor heat exchangers, and an expansion device disposed between the indoor and outdoor heat exchangers. The method may include receiving a first air temperature value of air upstream of the indoor heat exchanger from a return-air temperature sensor; receiving a second air temperature of air downstream of the indoor heat exchanger from a supply-air temperature sensor; and determining a working-fluid-charge condition of the heat-pump system using a processor programmed to determine the working-fluid-charge condition based on the first and second air temperatures.

In some embodiments, the working-fluid-charge condition is determined based on the first and second air temperatures and a working-fluid temperature measured by a working-fluid temperature sensor disposed downstream the indoor heat exchanger when the heat-pump system is in a heating mode.

In some embodiments, the first and second air temperature values are acquired while the heat-pump system is operating in a heating mode.

In some embodiments, the working-fluid temperature sensor is disposed between the indoor heat exchanger and the expansion device.

In some embodiments, the processor is programmed to determine the working-fluid-charge condition based on a difference between the second air temperature and the first air temperature and a comparison of the difference with a predetermined value.

In some embodiments, the method may include receiving a working-fluid temperature of working-fluid flowing between the indoor and outdoor heat exchangers. The processor may be programmed to determine the working-fluid-charge condition of the heat-pump system based on the working-fluid temperature.

In some embodiments, the method includes receiving a working-fluid temperature of working-fluid flowing between the indoor heat exchanger and the expansion device when the heat-pump system is operating in a heating mode. The processor may be programmed to determine the working-fluid-charge condition of the heat-pump system based on the working-fluid temperature.

In some embodiments, the processor is programmed to determine the working-fluid-charge condition based a first difference between the second air temperature and the working-fluid temperature.

In some embodiments, the processor may be programmed to determine the working-fluid-charge condition based on a second difference between the second air temperature and the first air temperature.

In some embodiments, the processor is programmed to determine the working-fluid charge condition based only on a first comparison of the first difference with a first predetermined value and a second comparison of the second difference with a second predetermined value.

In some embodiments, the processor is programmed to determine the working-fluid-charge condition based a third difference between the working-fluid temperature and the second air temperature.

In some embodiments, the processor is programmed to determine the working-fluid charge condition based on a first comparison of the first difference with a first predetermined value, a second comparison of the second difference with a second predetermined value, and a third comparison of the third difference with a third predetermined value.

In some embodiments, the method includes generating a first alert with a notification device indicating that a fault condition of the heat-pump system is related to the working-fluid-charge condition; and generating a second alert with the notification device indicating that the fault condition of the heat-pump system is unrelated to an amount of working fluid in the heat-pump system.

In another form, the present disclosure provides a working-fluid circuit having a processor in communication with a return-air temperature sensor and a supply-air temperature sensor, a compressor circulating a working fluid between the indoor and outdoor heat exchangers, and an expansion device between the indoor and outdoor heat exchangers. The processor may be programmed to determine a working-fluid-charge condition of the working-fluid circuit based on a first air temperature of air upstream of the indoor heat exchanger from the return-air temperature sensor and a second air temperature of air downstream of the indoor heat exchanger from the supply-air temperature sensor.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a schematic representation of a heat-pump system according to the principles of the present disclosure;

FIG. 2 is a schematic representation of a plurality of sensors associated with the heat-pump system communicating with a remote processing device; and

FIG. 3 is a flow chart illustrating a method of determining a charge level according to the principles of the present disclosure.

Corresponding reference numerals indicate corresponding parts throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

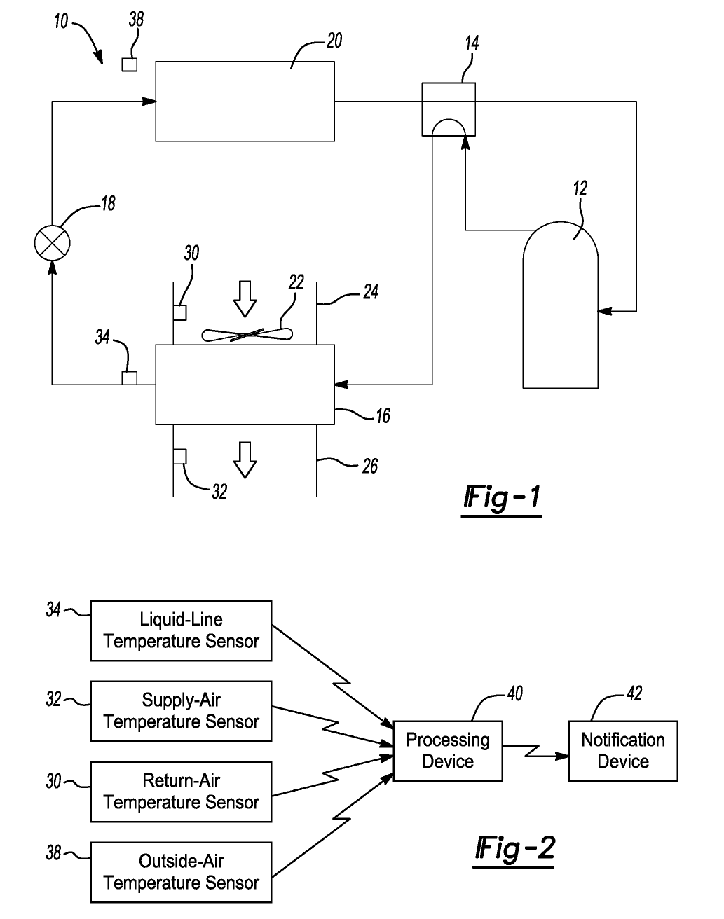

With reference to FIG. 1, a heat-pump system 10 is provided that may include a compressor 12, a reversing valve 14, an indoor heat exchanger 16, an expansion device 18, and an outdoor heat exchanger 20. The compressor 12 can be a scroll compressor, a reciprocating compressor, or a rotary vane compressor, for example, or any other type of compressor. The reversing valve 14 may be a four-way valve operable to control a direction of working fluid flow through the heat-pump system 10. A controller (not shown) may switch the reversing valve 14 between a first position (not shown) corresponding to a cooling mode and a second position corresponding to a heating mode (shown in FIG. 1).

In the cooling mode, the outdoor heat exchanger 20 may operate as a condenser or as a gas cooler and may cool discharge-pressure working fluid received from the compressor 12 by transferring heat from the working fluid to ambient air, for example. In the heating mode, the outdoor heat exchanger 20 may operate as an evaporator.

In the cooling mode, the indoor heat exchanger 16 may operate as an evaporator and may transfer heat from a space to be cooled (e.g., a room within a house or building) to the working fluid in the indoor heat exchanger 16. In the heating mode, the indoor heat exchanger 16 may operate as a condenser or as a gas cooler and may transfer heat from working fluid discharged from the compressor 12 to a space to be heated. During operation of the heat-pump system 10, a fan 22 may draw air from the space to be heated or cooled through a return-air duct 24 and force the air across the indoor heat exchanger 16 to transfer heat between the working fluid in the indoor heat exchanger 16 and the air. From the indoor heat exchanger 16, the heated or cooled air may be forced through a supply-air duct 26 to the space to be heated or cooled.

The heat-pump system 10 may also include a return-air temperature sensor 30, a supply-air temperature sensor 32, a liquid-line temperature sensor 34, and an outside-air temperature sensor 38. The return-air temperature sensor 30 may be disposed in the return-air duct 24 and may measure a temperature of the air flowing therethrough. The supply-air temperature sensor 32 may be disposed in the supply-air duct 26 and may measure a temperature of the air flowing therethrough. The liquid-line temperature sensor 34 may be disposed between the indoor heat exchanger 16 and the expansion device 18 and may measure a temperature of the working fluid flowing therebetween. The outside-air temperature sensor 38 may be disposed in any suitable location to measure a temperature of ambient air outside of the house or building.

As shown in FIG. 2, the sensors 30, 32, 34, 38 may be in communication with a remotely located or on-site processing device 40. In some embodiments, any or all of the sensors 30, 32, 34, 38 may be installed in the locations described above. In some embodiments, any or all of the sensors 30, 32, 34, 38 may be handheld sensors that a technician may temporarily place in the locations described above, obtain temperature measurements in those locations, and transmit the data to the processing device 40. Any or all of the sensors 30, 32, 34, 38 may be incorporated into a newly installed heat-pump system, or any or all of the sensors 30, 32, 34, 38 may be retrofitted to a pre-existing heat-pump system that has already been installed within a house or building. In some configurations, the outside-air temperature sensor 38 could be a thermometer or other sensor of a weather monitoring and/or weather reporting system or entity. In such configurations, the processor 40 may obtain the outside-air temperature measured by the sensor 38 from the weather monitoring and/or weather reporting system or entity via an internet, Bluetooth® or cellular connection, for example.

The processing device 40 may include a cloud-computing module having hardware (e.g., a processor and/or memory) and software capable of carrying the functionality described below. The processing device 40 may be in communication with a server that may receive data from the sensors 30, 32, 34, 38 via an internet connection or cellular network, for example. The processing device 40 may receive data from the sensors 30, 32, 34, 38 on demand, intermittently or in real time. In some embodiments, the processing device 40 may be located on a contractor or technician's portable computing device (e.g., a laptop, tablet, smartphone or other device), or may be located within the house or building in which the heat-pump system 10 is installed (e.g., in a thermostat (not shown) or a control module (not shown) for the heat-pump system 10).

The processing device 40 may also be in communication with one or more notification devices 42 that may be disposed remotely from the processing device 40 and/or the sensors 30, 32, 34, 38. The notification devices 42 may include any of a desktop computer, a laptop computer, a hand-held computing device, a tablet, or a smartphone, for example, or any other computing device or electronic information display device. In some embodiments, the one or more notification devices 42 may be a part of a wall-mounted thermostat unit.

As will be subsequently described, the processing device 40 may, based on data received from one or more of the sensors 30, 32, 34, 38, diagnose faults conditions (e.g., undercharge conditions, overcharge conditions and/or flow restriction conditions) of the heat-pump system 10, verify a charge level of the heat-pump system 10, and/or provide guidance to a technician during initial installation of the heat-pump system 10 for adding an appropriate amount of working fluid into the heat-pump system 10. Notifications, alerts, updates and/or other information output from the processing device 40 may be transmitted to one or more notification devices 42 and may be accessed or displayed thereon. In some embodiments, the notifications, alerts, updates and/or other information output from the processing device 40 may be transmitted to the notification device 42 via email, text message, instant message, multimedia message. In some embodiments, the notification device 42 may include a mobile application (e.g., a smartphone or tablet application) that provides notifications, alerts, updates, and/or other information based on output from the processing device 40.

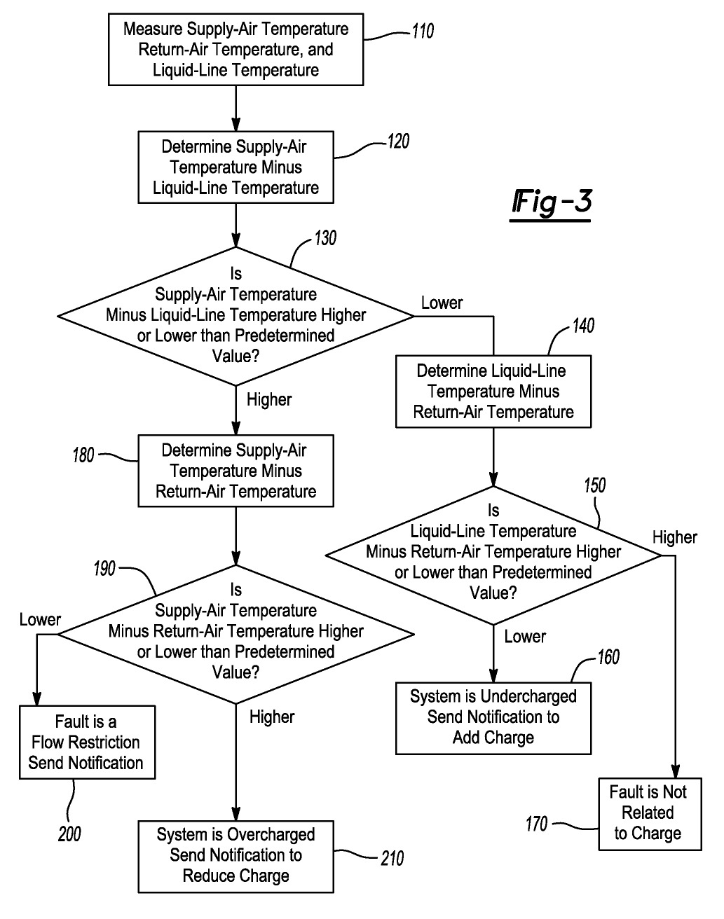

With reference to FIGS. 1-3, a method of diagnosing a fault condition when the heat-pump system 10 is in a heating mode will be described in detail. The method may include determining whether a reason for inefficient and/or ineffective operation of the heat-pump system 10 is an undercharge condition (i.e., not enough working fluid in the heat-pump system 10), an overcharge condition (i.e., too much working fluid in the heat-pump system 10), or a flow restriction in the heat-pump system 10 (e.g., a working-fluid-flow restriction in the liquid line or an airflow restriction at the outdoor heat exchanger 20 or at the indoor heat exchanger 16).

At step 110, the return-air temperature sensor 30, supply-air temperature sensor 32, and the liquid-line temperature sensor 34 may detect temperatures at their respective locations and transmit this data to the processing device 40. As described above, detecting and transmitting this data may be done on-demand, intermittently, averaged over a time period, or in real time. At step 120, the processing device 40 may determine a value equal to supply-air temperature minus a liquid-line temperature. When the heat-pump system 10 is operating in the heating mode, the liquid-line temperature may be a temperature detected by the liquid-line temperature sensor 34.

At step 130, the processing device 40 may determine if the value calculated at step 120 (supply-air temperature minus liquid-line temperature) is higher or lower than a first predetermined value. The first predetermined value may correspond to a particular heat pump system and/or may be based on a current outside-air temperature determined by the outside-air temperature sensor 38.

If the processing device 40 determines (at step 130) that the value determined at step 120 is lower than the first predetermined value, the processing device 40 may calculate, at step 140, a value equal to liquid-line temperature minus a return-air temperature. At step 150, the processing device 40 may determine if the value calculated at step 140 (liquid-line temperature minus return-air temperature) is higher or lower than a second predetermined value. The second predetermined value may correspond to a particular heat-pump system and/or may be based on a current outside-air temperature determined by the outside-air temperature sensor 38. If, at step 150, the processing device 40 determines that the value calculated at step 140 is lower than the second predetermined value, then the processing device 40 may, at step 160, send a notification to the notification device 42 indicating that the heat-pump system 10 is undercharged and working fluid should be added to the heat-pump system 10. If, at step 150, the processing device 40 determines that the value calculated at step 140 is higher than the second predetermined value, then the processing device 40 may, at step 170, determine that the system charge is adequate and/or any system fault may not be related to system charge.

If, at step 130, the processing device 40 determines that the value determined at step 120 is higher than the first predetermined value, the processing device 40 may calculate, at step 180, a value equal to supply-air temperature minus return-air temperature. At step 190, the processing device 40 may determine if the value calculated at step 180 (supply-air temperature minus return-air temperature) is higher or lower than a third predetermined value. The third predetermined value may correspond to a particular heat-pump system and/or may be based on a current outside-air temperature determined by the outside-air temperature sensor 38. If, at step 190, the processing device 40 determines that the value calculated at step 180 is lower than the third predetermined value, then the processing device 40 may, at step 200, send a notification to the notification device 42 indicating that there is a working fluid flow restriction in the heat-pump system 10. If, at step 190, the processing device 40 determines that the value calculated at step 180 is higher than the third predetermined value, then the processing device 40 may, at step 210, send a notification to the notification device 42 indicating that the heat-pump system 10 is overcharged and an amount of working fluid in the heat-pump system 10 should be reduced.

In addition to diagnosing a fault of the heat-pump system 10, the processing device 40 may perform the above method steps to verify a charge of the heat-pump system 10 on-demand or at predetermined time intervals, for example. If the processing device 40 determines that the heat-pump system 10 is overcharged, undercharged and/or some other fault condition exists, the processing device 40 may send an appropriate notification to the notification device 42, as described above.

The processing device 40 and notification device 42 may also be used by a technician to perform an initial charge of the heat-pump system 10 during the initial installation of the heat-pump system 10 into the house or building. That is, real time supply-air, return-air, liquid-line and outside-air temperature measurements can be processed by the processing device 40 and real-time feedback from the processing device 40 can be provided to the technician via the notification device 42 that indicates when the heat-pump system 10 has reached an optimum charge level (i.e., when the technician should stop adding working fluid to the heat-pump system 10).

For example, the processing device 40 may monitor (in real time) a value of liquid-line temperature minus return-air temperature. This value may continue to increase as the technician adds working fluid during the initial system charge until an optimum charge level is achieved. Once the optimum charge level is achieved, adding more working fluid to the heat-pump system 10 may cause the value of liquid-line temperature minus return-air temperature to decrease. Therefore, the processing device 40 and notification device 42 may notify the technician as soon as the value of liquid-line temperature minus return-air temperature starts to decrease. When the technician receives this notification, he or she may stop adding working fluid to the heat-pump system 10.

The first, second and third predetermined values described above may be chosen to correspond to a particular heat-pump system and may be determined through experimentation or from look-up tables, for example.

In this application, including the definitions below, the term module may be replaced with the term circuit. The term module may refer to, be part of, or include an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor (shared, dedicated, or group) that executes code; memory (shared, dedicated, or group) that stores code executed by a processor; other suitable hardware components that provide the described functionality; or a combination of some or all of the above, such as in a system-on-chip.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. As used herein, the phrase at least one of A, B, and C should be construed to mean a logical (A or B or C), using a non-exclusive logical OR. It should be understood that one or more steps within a method may be executed in different order (or concurrently) without altering the principles of the present disclosure.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method of monitoring a heat-pump system having indoor and outdoor heat exchangers, a compressor adapted to circulate a working fluid between the indoor and outdoor heat exchangers, and an expansion device disposed between the indoor and outdoor heat exchangers, the method comprising:
receiving a first air temperature value of air upstream of the indoor heat exchanger from a return-air temperature sensor;
receiving a second air temperature of air downstream of the indoor heat exchanger from a supply-air temperature sensor; and
determining a working-fluid-charge condition of the heat-pump system using a processor programmed to determine the working-fluid-charge condition based on the first and second air temperatures.

2. The method of claim 1, wherein the working-fluid-charge condition is determined based on the first and second air temperatures and a working-fluid temperature measured by a working-fluid temperature sensor disposed downstream of the indoor heat exchanger when the heat-pump system is operating in a heating mode.

3. The method of claim 2, wherein the first and second air temperature values are acquired while the heat-pump system is operating in a heating mode.

4. The method of claim 1, wherein the processor is programmed to determine the working-fluid-charge condition based on a difference between the second air temperature and the first air temperature and a comparison of the difference with a predetermined value.

5. The method of claim 1, further comprising receiving a working-fluid temperature of working-fluid flowing between the indoor heat exchanger and the expansion device when the heat-pump system is operating in a heating mode, wherein the processor is programmed to determine the working-fluid-charge condition of the heat-pump system based on the working-fluid temperature.

6. The method of claim 5, wherein the processor is programmed to determine the working-fluid-charge condition based a first difference between the second air temperature and the working-fluid temperature.

7. The method of claim 6, wherein the processor is programmed to determine the working-fluid-charge condition based on a second difference between the second air temperature and the first air temperature.

8. The method of claim 7, wherein the processor is programmed to determine the working-fluid charge condition based only on a first comparison of the first difference with a first predetermined value and a second comparison of the second difference with a second predetermined value.

9. The method of claim 7, wherein the processor is programmed to determine the working-fluid-charge condition based a third difference between the working-fluid temperature and the second air temperature.

10. The method of claim 9, wherein the processor is programmed to determine the working-fluid charge condition based on a first comparison of the first difference with a first predetermined value, a second comparison of the second difference with a second predetermined value, and a third comparison of the third difference with a third predetermined value.

11. The method of claim 10, further comprising generating a first alert with a notification device indicating that a fault condition of the heat-pump system is related to the working-fluid-charge condition; and generating a second alert with the notification device indicating that the fault condition of the heat-pump system is unrelated to an amount of working fluid in the heat-pump system.
